(19) United States
(12) Patent Application Publication
(10) Pub. No.: US 2023/0413660 A1
(43) Pub. Date: Dec. 21, 2023

(54) HYBRID ORGANIC-INORGANIC CONDUCTIVE THIN FILM AND ELECTRONIC ELEMENT HAVING THE SAME

(71) Applicant: NATIONAL TSING HUA UNIVERSITY, Hsinchu (TW)

(72) Inventors: JWO-HUEI JOU, Hsinchu (TW); JIN-TING LIN, Hsinchu (TW); MING-HUI CHENG, Hsinchu (TW); YU-HONG LIANG, Hsinchu (TW)

(73) Assignee: NATIONAL TSING HUA UNIVERSITY, Hsinchu (TW)

(21) Appl. No.: 18/083,678

(22) Filed: Dec. 19, 2022

(30) Foreign Application Priority Data
Jun. 15, 2022 (TW) 111122152

(51) Int. Cl. H10K 85/10

(52) U.S. Cl. CPC H01L 51/0037; H01L 51/5088; H01L 51/0039; H01L 51/0042

(57) ABSTRACT

A hybrid organic-inorganic conductive thin film comprising an organic layer and a plurality of inorganic particles is disclosed, wherein the plurality of inorganic particles comprises a plurality of Cu particles that have an average particle size in a range between 20 nm and 45 nm. This hybrid organic-inorganic conductive thin film is allowed to be used as a hole injection layer (HIL) or a hole transport layer (HTL), so as to be applied in the manufacture of QLED element, OLED element, organic photovoltaic element, hybrid inorganic-organic photovoltaic element, O-FET, O-TFT, or photoreceptor. Moreover, experiment data have proved that, compared to the regular OLED element, the OLED element having the HIL made of the hybrid organic-inorganic conductive thin film has a significant enhancement in device efficiency.

### BACKGROUND OF THE INVENTION

### 1. Field of the Invention

The present invention relates to the technology field of optoelectronic devices, and more particularly to a conductive polymeric film doped with inorganic nanoparticles for use in the manufacture of an optoelectronic device like OLED.

### 2. Description of the Prior Art

Conductive polymeric materials have highly attracted attention over the past several years mainly due to their potential advantage of low-cost, large-area, light-weight and vacuum-free fabrication. For example, it is allowed to form a PEDOT:PSS layer on a transparent substrate for acting as a transparent conductive film through spin coating process. Nowadays, PEDOT:PSS has been commonly used in the manufacture of a hole injection layer (HIL) and/or a hole transport layer (HTL) of an OLED element, a QLED element or an organic photovoltaic element. It is worth mentioning that, molybdenum oxide (MoOx) is also employed in the OLED devices as an effective HIL due to its matched work function with ITO electrode and low surface roughness and high transparency. However, the MoOx as HIL is normally prepared by using vacuum thermal evaporation method which is not a good candidate for low-cost OLED preparation. On the other hand, conductive polymeric materials are also applied in the development of various advanced electronic elements, including photoreceptor, organic field-effect transistor (O-FET) and organic thin-film transistor (O-TFT).

Literature 1 has reported that, the performance of an OLED element is significantly enhanced by doping silver (Ag) nanoparticles into the hole injection layer of the OLED element. Herein, literature 1 is written by Kim et. al, and is entitled with “Effect of Silver Nanoparticles in the Hole Injection Layer on the Performance of Organic Light Emitting Diodes” so as to be published on MRS Online Proceedings Library (OPL), Volume 936 (2006):Symposium L—Materials for Next-Generation Display Systems. Literature 2 has reported that Au-doped conductive polymeric film, which is benefit for enhancing the conductivity, is allowed to be used in the manufacture of a polymer light-emitting diodes (PLED). Herein, literature 2 is written by Chandran et. al, and is entitled with “Effect of gold nanoparticles doped PEDOT:PSS in polymer light emitting diodes” so as to be published on 12^{th} International Conference on Fibre Optics and Photonics 2014, DOI:10.1364/PHOTONICS.2014.T3A.84. Furthermore, literature 3 has reported that, the performance of a QLED element is significantly enhanced by doping Au nanoparticles into the hole injection layer of the QLED element. Herein, literature 3 is written by Chen et. al, and is entitled with “Enhanced Performance of Quantum Dot-Based Light-Emitting Diodes with Gold Nanoparticle-Doped Hole Injection Layer” so as to be published on 12^{th} Nanoscale Res Lett. 2016, DOI: 10.1186/s11671-016-1573-8.

According to the reports of the literatures 1-3, it is understood that doping inorganic nanoparticles into the conductive polymeric materials like PEDOT:PSS is a potential policy for enhancing the performance an organic optoelectronic element, such as OLED element, QLED element and organic photovoltaic element. However, absorption spectrum of FIG. 1 has revealed that, the absorption bandwidth of Au nanoparticles and Ag nanoparticles are both limited below 520 nm. Hence, doping Au/Ag nanoparticles in the HIL and/or the HTL is helpful in the enhancement of the performance of the blue OLED/QLED element and the green OLED/QLED element. However, doping Au/Ag nanoparticles in the HIL and/or the HTL fails to effectively enhance the performance of the red OLED/QLED element.

Furthermore, literature 4 has reported that, the electroluminescent performance of an OLED/QLED element has been improved by introducing a 2D material between the anode and the HTL of the OLED and utilizing the surface plasmon resonance (SPR) of Au nanoparticles. Herein, literature 4 is written by Feng et. al, and is entitled with “Plasmonic-Enhanced Organic Light-Emitting Diodes Based on a Graphene Oxide/Au Nanoparticles Composite Hole Injection Layer” so as to be published on Frontiers in Materials 5:75, DOI: 10.3389/fmats.2018.00075. However, related researches have further reported that, AuNPs and AgNPs dispersed in polymer material absorb visible light at their SPR absorbance maximum (approx. 520 nm). Therefore, few research has reported that doping AuNPs and AgNPs into conductive polymer material can enhance the performance of deep red OLED/QLED and deep blue OLED/QLED.

According to above descriptions, there are still rooms for improvement in the conventional AuNPs/AgNPs doped conductive polymeric film (e.g., HIL or HTL). In view of this fact, inventors of the present application have made great efforts to make inventive research and eventually provided a hybrid organic-inorganic conductive thin film and an electronic element having the same.

### SUMMARY OF THE INVENTION

The primary objective of the present invention is to disclose a hybrid organic-inorganic conductive thin film, comprising an organic layer and a plurality of inorganic particles spread in the organic layer, wherein the plurality of inorganic particles comprises a plurality of Cu particles that have an average particle size in a range between 20 nm and 45 nm. It is worth mentioning that, the hybrid organic-inorganic conductive thin film can be used as a hole injection layer (HIL) or a hole transport layer (HTL), so as to be applied in the manufacture of QLED element, OLED element, organic photovoltaic element, hybrid inorganic-organic photovoltaic element, photoreceptor, organic field-effect transistor (O-FET), or organic thin-film transistor (O-TFT). Moreover, experiment data have proved that, compared to the regular OLED element, the OLED element having the HIL made of the hybrid organic-inorganic conductive thin film has a significant enhancement in device efficiency.

For achieving the primary objective mentioned above, the present invention provides an embodiment of the hybrid organic-inorganic conductive thin film, comprising:
a polymer layer made of an organic material; and
a plurality of inorganic particles, being spread in the polymer layer by a volume percentage concentration in a range between 0.3 Vol % and 10 Vol %;
wherein the plurality of inorganic particles comprise a plurality of Cu particles, and the plurality of Cu particles having an average size in a range between 10 nm and 50 nm.

In one embodiment, the polymer layer has a thickness in a range between 30 nm and 55 nm.

In a practicable embodiment, the plurality of inorganic particles further comprise a plurality of Cu₂O particles, and the plurality of Cu₂O particles having an average size in a range between 10 nm and 50 nm.

In one embodiment, the electronic element is selected from a group consisting of QD electroluminescent element, organic electroluminescent element, organic photovoltaic element, inorganic-organic hybrid photovoltaic element, photoreceptor, organic field-effect transistor (O-FET), and organic thin-film transistor (O-TFT).

In one embodiment, the polymer layer acts as a hole injection layer (HIL), and the organic material is selected from a group consisting of poly(3,4-ethylenedioxythiophene)-poly(styrenesulfonate), poly(3-Methylthiophene), polypyrrole, polythiophene, and polyaniline.

In one embodiment, the polymer layer acts as a hole transport layer (HTL), and the organic material is selected from a group consisting of poly(3,4-ethylenedioxythiophene)-poly(styrenesulfonate), poly(N,N′-bis(4-butylphenyl)-N,N′-bis(phenyl)benzidine), poly[N,N′-bis(4-butylphenyl)-N,N′-bis(phenyl)-benzidine], tris(4-carbazoyl-9-ylphenyl)amine, and poly(9,9-dioctylfluorene-co-N-(4-butylphenyl)diphenylamine).

Moreover, the present invention also provides an embodiment of an electronic element for acting as an organic electroluminescent device, comprising:
an anode layer;
a hole injection layer formed on the anode layer, comprising:
a polymer layer made of an organic material; and
a plurality of inorganic particles, being spread in the polymer layer by a volume percentage concentration in a range between 0.3 Vol % and 10 Vol %; wherein the plurality of inorganic particles comprise a plurality of Cu particles, and the plurality of Cu particles having an average size in a range between 10 nm and nm;
an emission layer formed on the hole injection layer;
an electronic transport layer formed on the emission layer;
an electronic injection layer formed on the electronic transport layer; and
   a cathode layer.

In one embodiment, the polymer layer has a thickness in a range between 30 nm and 55 nm.

In one practicable embodiment, the plurality of inorganic particles further comprise a plurality of Cu₂O particles, and the plurality of Cu₂O particles having an average size in a range between 10 nm and 50 nm.

In one embodiment, the organic material is selected from a group consisting of poly(3,4-ethylenedioxythiophene)-poly(styrenesulfonate), poly(3-Methylthiophene), polypyrrole, polythiophene, and polyaniline.

In another one practicable embodiment, the electronic element further comprises a hole transport layer formed between the hole injection layer and the emission layer.

In one embodiment, the emission layer comprises a host portion and at least one dye material doped in the host portion.

Furthermore, the present invention proposes an electronic element, which is selected from a group consisting of QD electroluminescent element, organic electroluminescent element, organic photovoltaic element, inorganic-organic hybrid photovoltaic element, photoreceptor, organic field-effect transistor (O-FET), and organic thin-film transistor (O-TFT); characterized in that wherein the electronic element has a hybrid organic-inorganic conductive thin film, and the hybrid organic-inorganic conductive thin film comprises:
a polymer layer made of an organic material; and
a plurality of inorganic particles, being spread in the polymer layer by a volume percentage concentration in a range between 0.3 Vol % and 10 Vol %;
wherein the plurality of inorganic particles comprise a plurality of Cu particles, and the plurality of Cu particles having an average size in a range between 10 nm and 50 nm.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows an absorption spectrum of metal nanoparticles;

FIG. 2 shows a schematic stereo diagram of a hybrid organic-inorganic conductive thin film according to the present invention;

FIG. 3 shows a TEM image of a Cu particle spread in a polymer layer;

FIG. 4 shows an absorption spectrum of Cu particles and Cu₂O particles;

FIG. 5 shows a first cross-sectional view of an OLED element composing of the hybrid organic-inorganic conductive thin film of the present invention; and

FIG. 6 shows a second cross-sectional view of the OLED element.

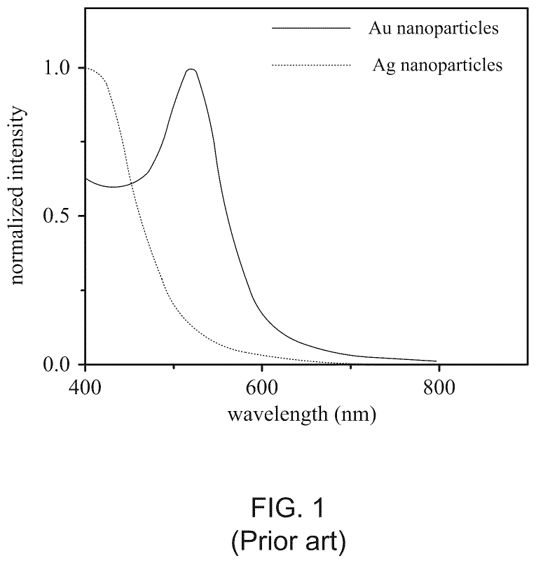

### DETAILED DESCRIPTION OF THE PREFERRED EMBODIMENTS

To more clearly describe a hybrid organic-inorganic conductive thin film and an electron element composing a hybrid organic-inorganic conductive thin film, surface inspection system for foil article according to the present invention, embodiments of the present invention will be we will described in detail with reference to the attached graphs drawings hereinafter.

### Hybrid Organic-Inorganic Conductive Thin Film

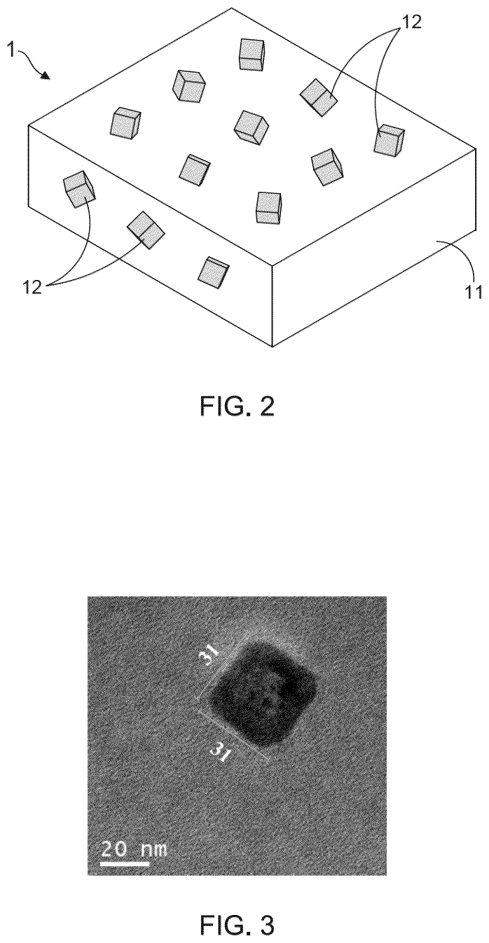

FIG. 2 shows a schematic stereo diagram of a hybrid organic-inorganic conductive thin film according to the present invention. As FIG. 2 shows, the present invention discloses a hybrid organic-inorganic conductive thin film 1, which is allowed to be used as a hole injection layer (HIL) or a hole transport layer (HTL), so as to be applied in the manufacture of QLED element, OLED element, organic photovoltaic element, inorganic-organic hybrid photovoltaic element, O-FET, O-TFT, or photoreceptor. According to the present invention, the hybrid organic-inorganic conductive thin film 1 principally comprises a polymer layer 11 and a plurality of inorganic particles 12, wherein the plurality of inorganic particles 12 are spread in the polymer layer 11 by a volume percentage concentration in a range between 0.3 Vol % and 10 Vol %. In one embodiment, the polymer layer 11 has a thickness in a range between 30 nm and 55 nm, and the plurality of inorganic particles comprise a plurality of Cu particles, of which the plurality of Cu particles have an average size in a range between 10 nm and 50 nm.

To describe in detail, in case of the polymer layer 11 acting as a hole injection layer (HIL), the polymer layer 11 is made of PEDOT:PSS (i.e., poly(3,4-ethylene dioxythiophene)-poly(styrenesulfonate)), PMeT (i.e., poly(3-Methylthiophene)), polypyrrole, polythiophene, or polyaniline On the other hand, in case of the polymer layer 11 acting as a hole transport layer (HTL), the polymer layer 22 is made of PEDOT:PSS, PTPD (i.e., poly(N,N′-bis(4-butylphenyl)-N,N′-bis(phenyl)benzidine)), PVK (i.e., Poly(9-vinylcarbazole), poly-TPD (i.e., poly[N,N′-bis(4-butylphenyl)-N,N′-bis(phenyl)-benzidine]), TCTA (i.e., tris(4-carbazoyl-9-ylphenyl)amine), or TFB (i.e., poly(9,9-dioctylfluorene-co-N-(4-butylphenyl)diphenylamine)).

FIG. 3 shows a TEM (Transmission Electron Microscope) image of a Cu particle spread in the polymer layer 11. FIG. 2 and FIG. 3 depict that the hybrid organic-inorganic conductive thin film 1 of the present invention is made by spreading a plurality of Cu particles (i.e., inorganic particles) in a polymer layer 11 made of an organic material like PEDOT:PSS. In the hybrid organic-inorganic conductive thin film 1, the plurality of Cu particles have an average size in a range between 20 nm and 45 nm. Taking FIG. 3 for example, the size of the Cu particle in the TEM image is 31 nm.

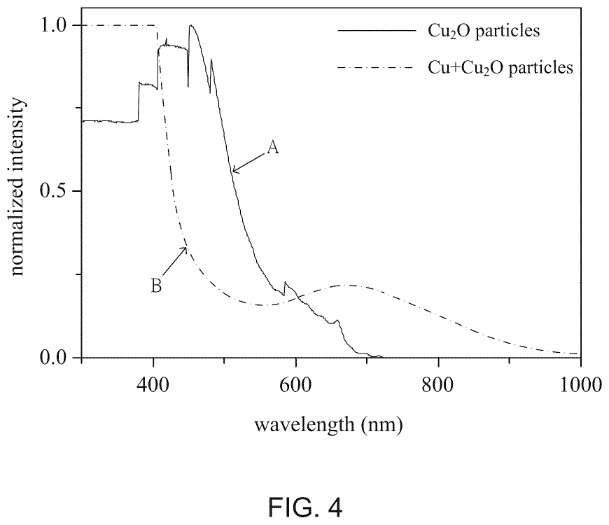

It has been known that, since nano-scale Cu particle has high specific surface energy and high activity, Cu particle is easy to be oxidized so as to become Cu₂O particle. FIG. 4 shows an absorption spectrum graph of Cu particles and Cu₂O particles. In FIG. 4, curve A is an absorption spectrum measured from Cu₂O particles, and curve B is an absorption spectrum measured from Cu₂O+Cu particles. According to curve A, it is observed that the intensity of the absorption spectrum of Cu₂O particles approaches 0 at wavelength around 700 nm. On the other hand, curve B shows that the intensity of the absorption spectrum of Cu₂O+Cu particles approaches 0 at wavelength around 1000 nm. Therefore, experimental data of FIG. 4 have revealed that, by making the inorganic particles 12 spread in the polymer layer 11 simultaneously include Cu₂O particles and Cu particles, the inorganic particles—12 certainly have an wide absorption band ranging from 300 nm to ˜1000nm. According to the present invention, the Cu₂O particles have an average size in a range between 10 nm and 50 nm.

### Experimental Data

For proving that the electronic element 1 using hybrid organic-inorganic conductive thin film 1 as a HIL or a HTL thereof indeed has an improved device performance, experiments are designed and then completed. In the experiments, multiple OLED elements are manufactured, such that the power efficacy (PE), the current efficacy (CE) and the external quantum efficiency (EQE) of each of the OLED elements are measured.

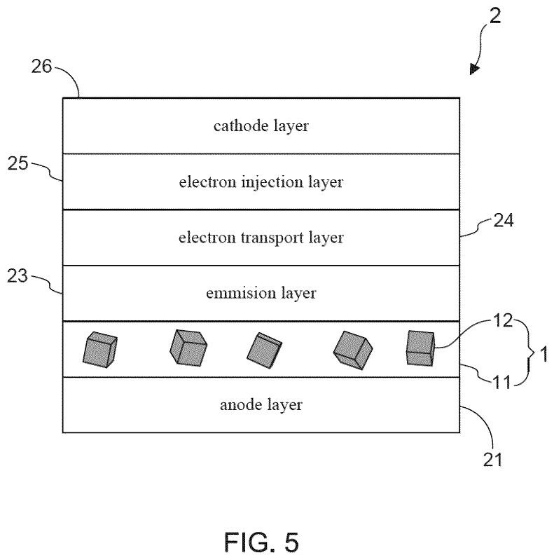

FIG. 5 shows a first cross-sectional view of an OLED element having the hybrid organic-inorganic conductive thin film of the present invention. Engineers skilled in development and manufacture of organic electroluminescent elements certainly know that, an OLED element 2 principally comprises: an anode layer 21, a hole injection layer (HIL), an emission layer (EML) 23, an electron transport layer (ETL) 24, an electron injection layer (EIL) 25, and a cathode layer 26. In the OLED element 2 shown in FIG. 5, the emission layer 23 comprises a host portion and at least one dye material doped in the host portion. Moreover, the hybrid organic-inorganic conductive thin film 1 comprising a polymer layer 11 and a plurality of inorganic particles 12 are used as the hole injection layer of the OLED element 2. Detail descriptions of each of the multiple function layers of the OLED element 2 are summarized in following tables (1)-(3).

TABLE 1
Blue OLED element

| Function layer | Material | Thickness (nm) |
|---|---|---|
| anode layer | ITO | 125 |
| polymer layer | PEDOT:PSS | 40 |
| of HIL | | |
| host layer | TCTA | 30 |
| of EML | | |
| blue dye | Flrpic | — |
| ETL | TPBi | 35 |
| EIL | LiF | 1 |
| cathode layer | Al | 100 |

TABLE 2
Green OLED element

| Function layer | Material | Thickness (nm) |
|---|---|---|
| anode layer | ITO | 125 |
| polymer layer | PEDOT:PSS | 40 |
| of HIL | | |
| host layer | TCTA | 30 |
| of EML | | |
| green dye | Ir(ppy)₃ | — |
| ETL | TPBi | 35 |
| EIL | LiF | 1 |
| cathode layer | Al | 100 |

TABLE 3
Red OLED element

| Function layer | Material | Thickness (nm) |
|---|---|---|
| anode layer | ITO | 125 |
| polymer layer | PEDOT:PSS | 40 |
| of HIL | | |
| host layer | TCTA | 30 |
| of EML | | |
| red dye | Ir(2-phq)₃ | — |
| ETL | TPBi | 35 |
| EIL | LiF | 1 |
| cathode layer | Al | 100 |

There is a need to further explain that, in each of the blue OLED element, the green OLED element and the red OLED element, a plurality of inorganic particles 12 are spread in the polymer layer 11 by a volume percentage concentration of 0.5 Vol %. Furthermore, related measurement data are integrated in following tables (4)-(5). In table (4), remark “W/O” means that the OLED element includes regular HIL. On the contrary, remark “W” means that the OLED element uses the hybrid organic-inorganic conductive thin film 1 of the present invention as the HIL thereof. Therefore, the measurement data of tables (4)-(5) have revealed that, compared to the OLED element 2 including regular HIL, the OLED element having the HIL made of the hybrid organic-inorganic conductive thin film 1 has a significant enhancement in device efficiency.

TABLE 4

| | PEmax (%) | | CEmax (%) | | EQEmax (%) | |
|---|---|---|---|---|---|---|
| | W/O | W | W/O | W | W/O | W |
| blue OLED | 13 | 14 | 16 | 20 | 6.9 | 8.3 |
| element | | | | | | |
| green OLED | 52 | 60 | 50 | 57 | 14 | 16 |
| element | | | | | | |
| red OLED | 25 | 31 | 24 | 30 | 11 | 13 |
| element | | | | | | |

TABLE 5

| | PE increment | CE increment | EQE increment |
|---|---|---|---|
| | (%) | (%) | (%) |
| blue OLED | 6 | 23 | 20 |
| element | | | |
| green OLED | 15 | 15 | 16 |
| element | | | |
| red OLED | 23 | 23 | 23 |
| element | | | |

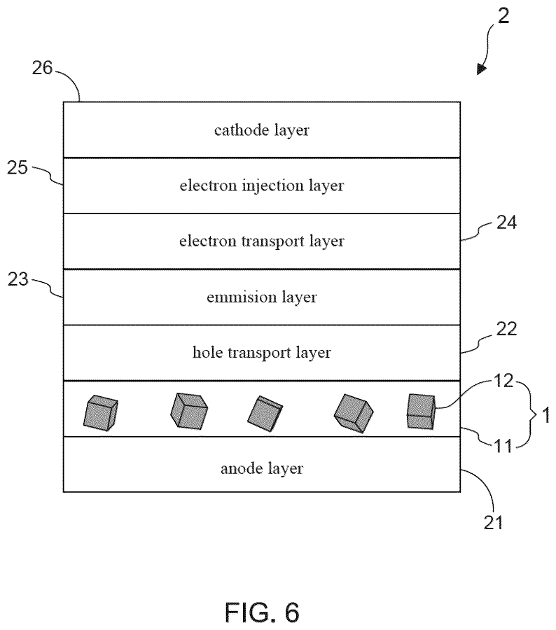

FIG. 6 shows a second cross-sectional view of an OLED element composing of the hybrid organic-inorganic conductive thin film of the present invention. Engineers skilled in development and manufacture of organic electroluminescent elements also know that, an OLED element 2 can also be designed to comprises: an anode layer 21, a hole transport layer (HTL) 22, a hole injection layer (HIL), an emission layer (EML) 23, an electron transport layer (ETL) 24, an electron injection layer (EIL) 25, and a cathode layer 26. In the OLED element 2 shown in FIG. 6, the emission layer 23 comprises a host portion and at least one dye material doped in the host portion. Moreover, the hybrid organic-inorganic conductive thin film 1 comprising a polymer layer 11 and a plurality of inorganic particles 12 are used as the HIL of the OLED element 2. Detail descriptions of each of the multiple function layers of the OLED element 2 are summarized in following tables (6)-(7).

TABLE 6
Deep-blue OLED element

| Function layer | Material | Thickness (nm) |
|---|---|---|
| anode layer | ITO | 125 |
| polymer layer | PEDOT:PSS | 40 |
| of HIL | | |
| HTL | poly(vinylcarbazole) | 30 |
| | (PVK) | |
| host layer | TCTA | 30 |
| of EML | | |
| deep-blue dye | 27CN3PI | — |
| ETL | TPBi | 35 |
| EIL | LiF | 1 |
| cathode layer | Al | 100 |

TABLE 7
Deep-red OLED element

| Function layer | Material | Thickness (nm) |
|---|---|---|
| anode layer | ITO | 125 |
| polymer layer | PEDOT:PSS | 40 |
| of HIL | | |
| HTL | mCP | 15 |
| host layer | TCTA | 30 |
| of EML | | |
| deep-red dye | cf3pzpy | — |
| ETL | TPBi | 35 |
| EIL | LiF | 1 |
| cathode layer | Al | 100 |

There is a need to further explain that, in each of the deep-blue OLED element and the deep-red OLED element, a plurality of inorganic particles 12 are spread in the polymer layer 11 by a volume percentage concentration of 0.5 Vol %. Furthermore, related measurement data are integrated in following tables (8)-(9). In table (8), remark “W/O” means that the OLED element includes regular HIL. On the contrary, remark “W” means that the OLED element uses the hybrid organic-inorganic conductive thin film 1 of the present invention as the HIL thereof. Therefore, the measurement data of tables (8)-(9) have revealed that, compared to the OLED element including regular HIL, the OLED element having the HIL made of the hybrid organic-inorganic conductive thin film 1 has a significant enhancement in device efficiency.

TABLE 8

| | PEmax (%) | | CEmax (%) | | EQEmax %) | |
|---|---|---|---|---|---|---|
| | W/O | W | W/O | W | W/O | W |
| deep-blue | 0.4 | 0.9 | 0.9 | 2.0 | 1.9 | 2.4 |
| OLED | | | | | | |
| element | | | | | | |
| deep-red | 5.1 | 6.2 | 8.2 | 9.9 | 11 | 14 |
| OLED | | | | | | |
| element | | | | | | |

TABLE 9

| | PE increment | CE increment | EQE increment |
|---|---|---|---|
| | (%) | (%) | (%) |
| deep-blue | 125 | 122 | 26 |
| OLED | | | |
| element | | | |
| deep-red | 22 | 21 | 24 |
| OLED | | | |
| element | | | |

As a result, experimental data have proved that, the hybrid organic-inorganic conductive thin film 1 of the present invention can indeed be used a HIL or a HTL, so as to be applied in the manufacture of QLED element, OLED element, organic photovoltaic element, hybrid inorganic-organic photovoltaic element, O-FET, O-TFT, or photoreceptor. Moreover, experiment data have also proved that, compared to the regular OLED element, the OLED element having the HIL made of the hybrid organic-inorganic conductive thin film 1 has a significant enhancement in device efficiency.

Therefore, through above descriptions, all embodiments and their constituting elements of the hybrid organic-inorganic conductive thin film according to the present invention have been introduced completely and clearly. Moreover, the above description is made on embodiments of the present invention. However, the embodiments are not intended to limit the scope of the present invention, and all equivalent implementations or alterations within the spirit of the present invention still fall within the scope of the present invention.

What is claimed is:

1. A hybrid organic-inorganic conductive thin film for being applicated in an electronic element, comprising:
a polymer layer made of an organic material; and
a plurality of inorganic particles, being spread in the polymer layer by a volume percentage concentration in a range between 0.3 Vol % and 10 Vol %;
wherein the plurality of inorganic particles comprise a plurality of Cu particles, and the plurality of Cu particles having an average size in a range between 10 nm and 50 nm.

2. The hybrid organic-inorganic conductive thin film of claim 1, wherein the polymer layer has a thickness in a range between 30 nm and 55 nm.

3. The hybrid organic-inorganic conductive thin film of claim 1, wherein the plurality of inorganic particles further comprise a plurality of Cu₂O particles, and the plurality of Cu₂O particles having an average size in a range between 10 nm and 50 nm.

4. The hybrid organic-inorganic conductive thin film of claim 1, wherein the electronic element is selected from a group consisting of QD electroluminescent element, organic electroluminescent element, organic photovoltaic element, hybrid inorganic-organic photovoltaic element, photoreceptor, organic field-effect transistor (O-FET), and organic thin-film transistor (O-TFT).

5. The hybrid organic-inorganic conductive thin film of claim 1, wherein the polymer layer acts as a hole injection layer (HIL), and the organic material is selected from a group consisting of poly(3,4-ethylenedioxythiophene)-poly(styrenesulfonate), poly(3-Methylthiophene), polypyrrole, polythiophene, and polyaniline.

6. The hybrid organic-inorganic conductive thin film of claim 1, wherein the polymer layer acts as a hole transport layer (HTL), and the organic material is selected from a group consisting of poly(3,4-ethylenedioxythiophene)-poly(styrenesulfonate), poly(9-vinylcarbazole), poly(N,N′-bis(4-butylphenyl)-N,N′-bis(phenyl)benzidine), poly[N,N′-bis(4-butylphenyl)-N,N′-bis(phenyl)-benzidine], tris(4-carbazoyl-9-ylphenyl)amine, di-[4-(N,N-di-p-tolyl-amino)-phenyl]cyclohexane, and poly(9,9-dioctylfluorene-co-N-(4-butylphenyl)diphenylamine)

7. An electronic element acting as an organic electroluminescent device, comprising:
an anode layer;
a hole injection layer formed on the anode layer, comprising:
a polymer layer made of an organic material; and
a plurality of inorganic particles, being spread in the polymer layer by a volume percentage concentration in a range between 0.3 Vol % and 10 Vol %; wherein the plurality of inorganic particles comprise a plurality of Cu particles, and the plurality of Cu particles having an average size in a range between 10 nm and nm;
an emission layer formed on the hole injection layer;
an electronic transport layer formed on the emission layer;
an electronic injection layer formed on the electronic transport layer; and
a cathode layer.

8. The electronic element of claim 7, wherein the polymer layer has a thickness in a range between 30 nm and 55 nm.

9. The electronic element of claim 7, wherein the plurality of inorganic particles further comprise a plurality of Cu₂O particles, and the plurality of Cu₂O particles having an average size in a range between 10 nm and 50 nm.

10. The electronic element of claim 7, wherein the organic material is selected from a group consisting of poly(3,4-ethylenedioxythiophene)-poly(styrenesulfonate), poly(3-Methylthiophene), polypyrrole, polythiophene, and polyaniline.

11. The electronic element of claim 7, further comprising a hole transport layer formed between the hole injection layer and the emission layer.

12. The electronic element of claim 7, wherein the emission layer comprises a host portion and at least one dye material doped in the host portion.

13. An electronic element, being selected from a group consisting of QD electroluminescent element, organic electroluminescent element, organic photovoltaic element, hybrid inorganic-organic photovoltaic element, photoreceptor, organic field-effect transistor (O-FET), and organic thin-film transistor (O-TFT); characterized in that wherein the electronic element has a hybrid organic-inorganic conductive thin film, and the hybrid organic-inorganic conductive thin film comprising:
a polymer layer made of an organic material; and
a plurality of inorganic particles, being spread in the polymer layer by a volume percentage concentration in a range between 0.3 Vol % and 10 Vol %;
wherein the plurality of inorganic particles comprise a plurality of Cu particles, and the plurality of Cu particles having an average size in a range between 10 nm and nm.
